(19) United States
(12) Patent Application Publication
(10) Pub. No.: US 2015/0194424 A1
(43) Pub. Date: Jul. 9, 2015

(54) SEMICONDUCTOR DEVICE AND METHOD FOR MANUFACTURING THE SAME

(71) Applicant: Kabushiki Kaisha Toshiba, Tokyo (JP)

(72) Inventor: Akihiro Imada, Yokohama (JP)

(21) Appl. No.: 14/458,830

(22) Filed: Aug. 13, 2014

Related U.S. Application Data
(60) Provisional application No. 61/923,816, filed on Jan. 6, 2014.

(51) Int. Cl. H01L 27/088; H01L 29/78; H01L 21/762; H01L 29/08; H01L 29/66; H01L 29/06; H01L 29/10

(52) U.S. Cl. CPC H01L 27/088; H01L 29/0653; H01L 29/7816; H01L 29/7835; H01L 29/1095; H01L 29/0873; H01L 29/66681; H01L 29/66659; H01L 21/762

(57) ABSTRACT

According to one embodiment, a semiconductor device includes an impurity region 7 of a first conductivity type between body regions (4, 5) of a second conductivity type and buried insulating layers (8, 9), which are formed in a semiconductor layer 3 of the first conductivity type. The impurity region 7 has an impurity concentration higher than that of the semiconductor layer 3. The body regions (4, 5) have source regions (10, 11). The source-side surfaces (80, 90) and source-side corners (81, 91) of the buried insulating layers (8, 9) are not covered by a drift region 6, but exposed to the semiconductor layer 3.

### CROSS-REFERENCE TO RELATED APPLICATIONS

This application is based upon and claims the benefit of priority from U.S. Provisional Application No. 61/923816, filed on Jan. 6, 2014; the entire contents of which are incorporated herein by reference.

### FIELD

Embodiments of the present invention relate to a semiconductor device and a method for manufacturing the same.

### BACKGROUND

Conventionally, a DMOS (Double-diffused MOS) transistor, wherein the channel region of the MOS transistor is formed by double diffusion, has been known as a high-voltage MOS transistor. Further, there have been disclosed semiconductor devices which comprise an EDMOS (Extended Drain MOS) transistor having a drift region surrounding a buried insulating layer formed between the source and drain regions. Because the drift region of high resistance lessens the source-to-drain electric field, the EDMOS transistor has a high-voltage transistor structure.

When the EDMOS transistor is in the ON-state, electrons or holes accelerated by the high electric field collide with a corner of the buried insulating layer, and thus impact ionization that creates electron-hole pairs occurs, and created impact ions are taken into the gate electrode, resulting in the degradation of the gate insulating layer or the degradation in current drive capability. Accordingly, there have been made various proposals for suppressing the creation of impact ions such as a change to the shape of the buried insulating layer.

### BRIEF DESCRIPTION OF THE DRAWINGS

FIGS. 1A and 1B are views schematically showing the semiconductor device according to a first embodiment of the present invention.

FIG. 2 is a graph for explaining the state of the impurity concentration of the semiconductor device of the first embodiment of the present invention.

FIGS. 3A and 3B are diagrams showing impact ion density in comparison with the case of a conventional structure.

FIGS. 4A to 4E are views schematically showing the manufacturing method of the semiconductor device according to a second embodiment of the present invention.

FIG. 5 is a view schematically showing the semiconductor device according to a third embodiment of the present invention.

FIG. 6 is a view schematically showing the semiconductor device according to a fourth embodiment of the present invention.

FIG. 7 is a view schematically showing the semiconductor device according to a fifth embodiment of the present invention.

### DETAILED DESCRIPTION

In general, according to one embodiment, a semiconductor device includes a semiconductor layer of a first conductivity type; a body region of a second conductivity type formed in the semiconductor layer; a source region of the first conductivity type formed in the body region of the second conductivity type; a buried insulating layer formed in the surface of the semiconductor layer and away from the body region of the second conductivity type; a gate insulating layer formed on the surface of the semiconductor layer of the first conductivity type and between the source region of the first conductivity type and the buried insulating layer; and a gate electrode formed on the gate insulating layer. Further, the semiconductor device comprises a drift region of the first conductivity type in the semiconductor layer of the first conductivity type, the drift region exposing the side surface and corner located under the gate electrode of the buried insulating layer and touching the bottom of the buried insulating layer and the side surface on the far side of the buried insulating layer from the gate electrode. Yet further, the semiconductor device comprises an impurity region of the first conductivity type formed between the body region of the second conductivity type and the buried insulating layer and away from the buried insulating layer in the semiconductor layer of the first conductivity type, the impurity region having an impurity concentration higher than that of the semiconductor layer of the first conductivity type. Further, the semiconductor device comprises a drain region of the first conductivity type formed in the drift region of the first conductivity type and touching the side surface on the far side of the buried insulating layer from the body region of the second conductivity type.

Exemplary embodiments of semiconductor devices and method for manufacturing the same will be explained below in detail with reference to the accompanying drawings. The present invention is not limited to the following embodiments.

### First Embodiment

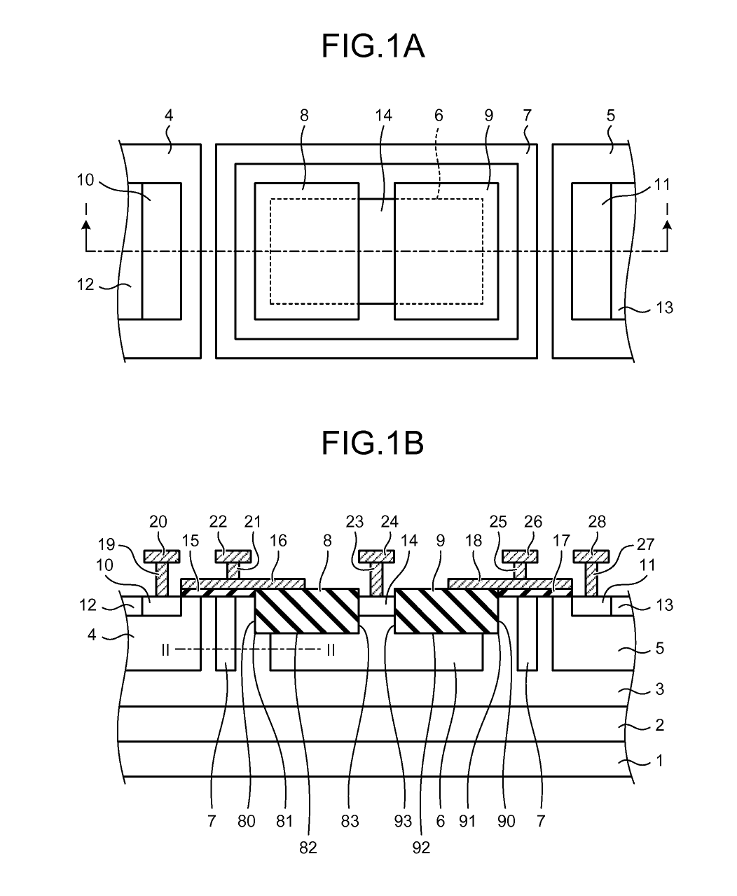

FIG. 1A is a plan view schematically showing the semiconductor device of the first embodiment of the present invention. FIG. 1B is a schematic cross-sectional view along dot-dashed line I-I of FIG. 1A. In FIG. 1A showing a schematic plan view, wirings and the like formed on the surface of the semiconductor device are omitted. The semiconductor device of the present embodiment has a P-type semiconductor substrate 1. It has an N-type buried layer 2 on the P-type semiconductor substrate 1. It has a P-type epitaxial layer 3 on the N-type buried layer 2. It has a first N-type body region 4 in the P-type epitaxial layer 3. It has a first P-type source region 10 in the first N-type body region 4. The present embodiment has a DMOS transistor structure where a channel region is formed by double diffusion between the P-type epitaxial layer 3 and the first P-type source region 10. It has a first N-type back gate region 12 in contact with the first P-type source region 10.

In the P-type epitaxial layer 3, there is a P-type drift region 6. Namely, the P-type drift region 6 is formed in the surface of the P-type epitaxial layer 3. The P-type drift region 6 has a higher impurity concentration than the P-type epitaxial layer 3. On the substrate surface side of the P-type drift region 6, there are two buried insulating layers (8, 9). The two buried insulating layers (8, 9) are constituted by, e.g., silicon oxide layers of an STI structure. There is a P-type drain region 14 between the two buried insulating layers (8, 9) and in the P-type drift region 6. The P-type drain region 14 touches the drain-side surface 83 of the first buried insulating layer 8 and the drain-side surface 93 of the second buried insulating layer 9. The present embodiment has an EDMOS structure where the P-type drift region 6 is provided between the source region 10 and the drain region 14. The P-type drift region 6 forms a high resistance region containing an impurity at a lower concentration as compared with the P-type drain region 14. Making the P-type drift region 6 a high resistance region lessens the source-to-drain electric field, thus providing a high-voltage P-type MOS transistor structure.

In part of the P-type epitaxial layer 3 between the first buried insulating layer 8 and the first N-type body region 4, there is a P-type impurity region 7 of a higher impurity concentration than the P-type epitaxial layer 3. The P-type impurity region 7 is formed away from the first buried insulating layer 8. That is, the P-type epitaxial layer 3 exists between the source-side surface 80 of the first buried insulating layer 8 and the P-type impurity region 7. Thus, the source-side corner 81 of the first buried insulating layer 8 is exposed to the P-type epitaxial layer 3.

On the surface of part of the P-type epitaxial layer 3 between the first P-type source region 10 and the first buried insulating layer 8, there is a first gate insulating layer 15. On the first gate insulating layer 15, there is a first gate electrode 16. The first gate electrode 16 extends onto the first buried insulating layer 8. Its extending onto the first buried insulating layer 8 produces a field plate effect, and thus the P-type DMOS transistor becomes higher in breakdown voltage.

On the plane of the figure, there is a second N-type body region 5 to the right of the second buried insulating layer 9. In part of the P-type epitaxial layer 3 between the second buried insulating layer 9 and the second N-type body region 5, there is the P-type impurity region 7 of a higher impurity concentration than the P-type epitaxial layer 3. The P-type impurity region 7 is formed away from the second buried insulating layer 9. That is, the P-type epitaxial layer 3 exists between the source-side surface 90 of the second buried insulating layer 9 and the P-type impurity region 7. Thus, the source-side corner 91 of the second buried insulating layer 9 is exposed to the P-type epitaxial layer 3. There is a second P-type source region 11 in the second N-type body region 5. There is a second N-type back gate region 13 in contact with the second P-type source region 11. The P-type DMOS transistor having a current path via the second P-type source region 11, the second N-type body region 5, and the P-type drift region 6 to the P-type drain region 14 is formed.

On the surface of part of the P-type epitaxial layer 3 between the second P-type source region 11 and the second buried insulating layer 9, there is a second gate insulating layer 17. On the second gate insulating layer 17, there is a second gate electrode 18. The second gate electrode 18 extends onto the second buried insulating layer 9. Its extending onto the second buried insulating layer 9 produces a field plate effect, and thus the P-type DMOS transistor becomes higher in breakdown voltage. The semiconductor device of the present embodiment has a left-right symmetric structure with respect to the P-type drain region 14. The P-type impurity region 7 surrounds the two buried insulating layers (8, 9), the P-type drift region 6, and the P-type drain region 14.

The semiconductor device has a source contact electrode 19 connected to the first P-type source region 10, a drain contact electrode 23 connected to the P-type drain region 14, a source contact electrode 27 connected to the second P-type source region 11, a source wiring 20 connected to the source contact electrode 19, a drain wiring 24 connected to the drain contact electrode 23, and a source wiring 28 connected to the source contact electrode 27. For example, the first P-type source region 10 and the first N-type back gate region 12, and the second P-type source region 11 and the second N-type back gate region 13 are connected respectively by other wirings formed separately, which wirings are omitted from the figure.

In the semiconductor device of the present embodiment, the P-type impurity region 7, which extends downward, that is, from the surface of the P-type epitaxial layer 3 toward the P-type semiconductor substrate 1, exists between the N-type body regions (4, 5) and the P-type drift region 6. The P-type impurity region 7 is in contact with the gate insulating layers (15, 17) at the surface of the P-type epitaxial layer 3. Since having a higher impurity concentration than the P-type epitaxial layer 3, the P-type impurity region 7 is lower in resistance than the P-type epitaxial layer 3. Since having a higher impurity concentration than the P-type epitaxial layer 3, the P-type drift region 6 has a lower resistance than the P-type epitaxial layer 3. The P-type drift region 6 exposes the source-side surfaces (80, 90) and source-side corners (81, 91) of the buried insulating layers (8, 9) to the P-type epitaxial layer 3, and touches the bottoms (82, 92) and the drain-side surfaces (83, 93) of the buried insulating layers (8, 9).

The source-side corners (81, 91) of the buried insulating layers (8, 9) are exposed to the P-type epitaxial layer 3 and thus surrounded by resistance higher than that of the P-type drift region 6, and hence a current path from the substrate surface via the P-type impurity region 7 to the P-type drift region 6 is more likely to be formed. That is, the current that flows from the P-type source regions (10, 11) to the P-type drift region 6 is spread toward the P-type semiconductor substrate 1, so that current flowing to the P-type drift region 6 but not via the source-side corners (81, 91) of the buried insulating layers (8, 9) increases. Hence, the quantity of holes colliding with the source-side corners (81, 91) of the buried insulating layers (8, 9) located under the gate electrodes (16, 18) is reduced, so that the quantity of impact ions created at the source-side corners (81, 91) of the buried insulating layers (8, 9) is held down. Setting the impurity concentration of the P-type impurity region 7 to be higher than that of the P-type epitaxial layer 3 so as to make the P-type impurity region 7 of lower resistance can reduce the resistance of the source-to-drain current path of the P-type DMOS transistor, resulting in an improvement in current drive capability.

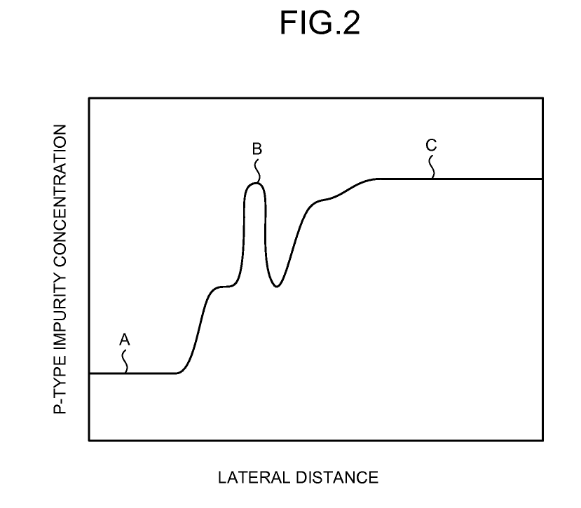

FIG. 2 is a graph showing the relation of the P-type impurity concentration along dot-dashed line II-II of the semiconductor device of the first embodiment shown in FIG. 1. In FIG. 2, the region indicated by A corresponds to the N-type body region 4; the region indicated by B corresponds to the P-type impurity region 7; and the region indicated by C corresponds to the P-type drift region 6. This shows that there is a structure where the P-type impurity region 7 of an impurity concentration higher than that of the P-type epitaxial layer 3 and nearly equal to that of the P-type drift region 6 exists between the first N-type body region 4 and the P-type drift region 6.

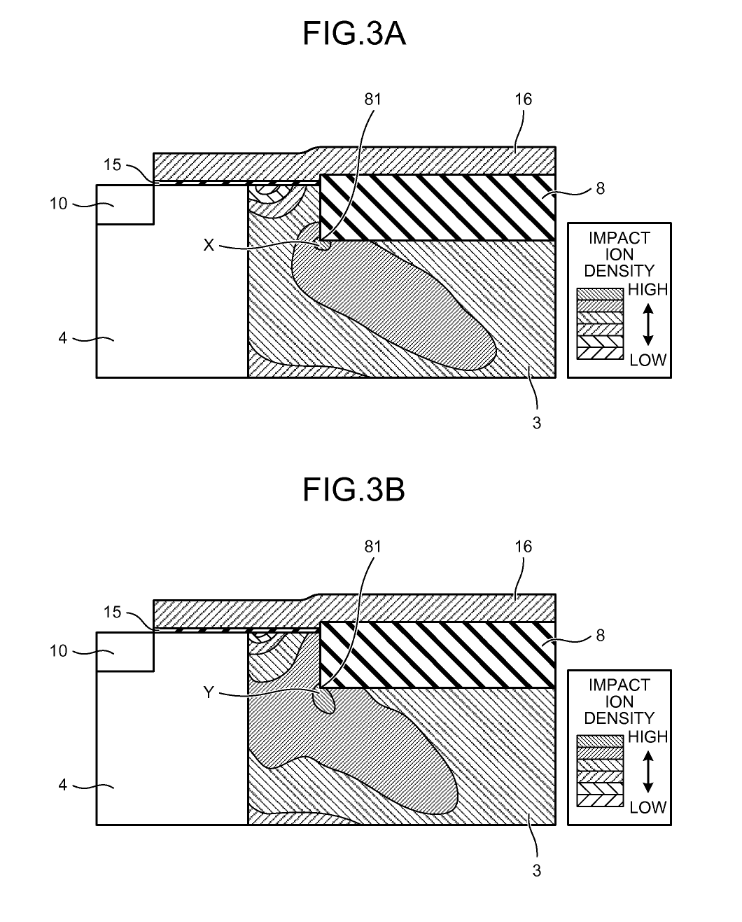

FIGS. 3A and 3B are diagrams for explaining the effect of the semiconductor device of the first embodiment. FIG. 3A shows the density distribution of impact ions in the semiconductor device of the first embodiment. It is the density distribution of impact ions in the case of the embodiment where with the P-type impurity region 7 provided between the first N-type body region 4 and the P-type drift region 6, the source-side corner 81 of the first buried insulating layer 8 located on the first P-type source region 10 side is exposed to the P-type epitaxial layer 3. The number of impact ions created per second and per cubic centimeter is represented as the density distribution. For convenience of description, only the density distribution of impact ions in the P-type epitaxial layer 3 is shown, and the P-type impurity region 7 is not shown. The area X located at the source-side corner 81 of the first buried insulating layer 8 has the highest creation density of impact ions.

FIG. 3B shows, for comparison, the density distribution of impact ions in the case of a structure where without the P-type impurity region 7 being provided, the corner 81 on the first source region 10 side of the first buried insulating layer 8 is covered by the P-type drift region 6. Compared with FIG. 3A showing the case of the present embodiment, the area Y that is the area of the highest impact ion density is larger in area. It is seen that according to the present embodiment, the creation area of impact ions of high density is narrowed and that thus the creation of impact ions is suppressed. Note that the simulation was conducted under conditions that with applying the maximum rated voltage across the source and drain, such a voltage as to maximize the gate current is applied to the gate electrode 16.

### Second Embodiment

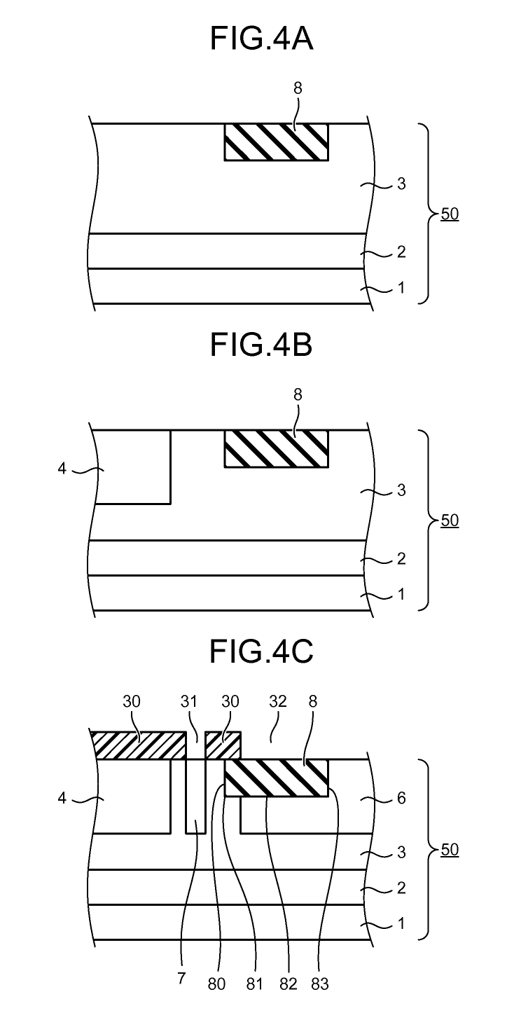

FIGS. 4A to 4B are schematic views for explaining one embodiment of a manufacturing method of the semiconductor device according to the first embodiment described with reference to FIG. 1. As already described, since the embodiment shown in FIG. 1 has a left-right symmetric structure with respect to the P-type drain region 14, one embodiment of the manufacturing method will be described with reference to the left part thereof. A semiconductor substrate 50 is prepared which has the P-type semiconductor substrate 1, the N-type buried layer 2 on the P-type semiconductor substrate 1, the P-type epitaxial layer 3 on the N-type buried layer 2, and the first buried insulating layer 8 formed in the P-type epitaxial layer 3. The first buried insulating layer 8 is formed, for example, by forming a shallow groove in the surface of the P-type epitaxial layer 3 by lithography and RIE (Reactive Ion Etching) and filling the groove with an oxide layer by CVD (Chemical Vapor Deposition) and then flattening the surface of the semiconductor substrate 50 by CMP (Chemical Mechanical Polishing) (FIG. 4A).

Next, by ion implanting, e.g., phosphorus that is an N-type impurity selectively at a position away from the first buried insulating layer 8 and performing heat treatment in a nitrogen atmosphere, the first N-type body region 4 is formed (FIG. 4B).

Then, a mask 30 having openings 31 and 32 is formed on the surface of the semiconductor substrate 50, and, e.g., boron is ion implanted through the openings 31 and 32 of the mask to form the P-type impurity region 7 and the P-type drift region 6 simultaneously (FIG. 4C).

Forming the P-type impurity region 7 and the P-type drift region 6 simultaneously enables manufacture without an additional impurity diffusion process for the P-type impurity region 7. As such, the source-side surface 80 and the source-side corner 81 of the first buried insulating layer 8 touch the P-type epitaxial layer 3. The bottom 82 and drain-side surface 83 of the first buried insulating layer 8 touch the P-type drift region 6. That is, the P-type drift region 6 exposes the source-side surface 80 and source-side corner 81 of the first buried insulating layer 8 to the P-type epitaxial layer 3 and touches the bottom 82 and drain-side surface 83 of the first buried insulating layer 8.

Note that a mask having an opening 31 and a mask having an opening 32 may be sequentially prepared and that the P-type impurity region 7 and the P-type drift region 6 may be formed by introducing P-type impurity through the openings of the masks respectively. Or first a semiconductor substrate having the P-type drift region 6 formed therein may be prepared, and the first buried insulating layer 8 may be formed in the surface of the semiconductor substrate. After the P-type impurity region 7 and the P-type drift region 6 are formed, the first N-type body region 4 can be formed. The order of the manufacture steps is not limited to the embodiment.

Then, the mask 30 is removed, and the surface of the semiconductor substrate 50 is oxidized in an oxygen atmosphere, thereby forming an oxide layer 40 over the entire surface of the semiconductor substrate 50 (FIG. 4D).

Then, for example, a conductive layer (not shown) made of polycrystalline silicon doped with an impurity is formed on the oxide layer 40 and is patterned by a lithography technique and an RIE technique to form the first gate electrode 16. Next, a P-type impurity such as boron is implanted selectively into the N-type body region 4 and the P-type drift region 6, and heat treatment is performed in a nitrogen atmosphere to form the first P-type source region 10 and the P-type drain region 14. Then, an N-type impurity such as arsenic is implanted into the N-type body region 4, and heat treatment is performed in a nitrogen atmosphere to form the first N-type back gate region 12. Thereafter, a source-contact electrode 19, a gate-contact electrode 21, a drain-contact electrode 23, a source wiring 20, a gate wiring 22, and a drain wiring 24 are formed by the lithography technique and the RIE technique (FIG. 4E).

### Third Embodiment

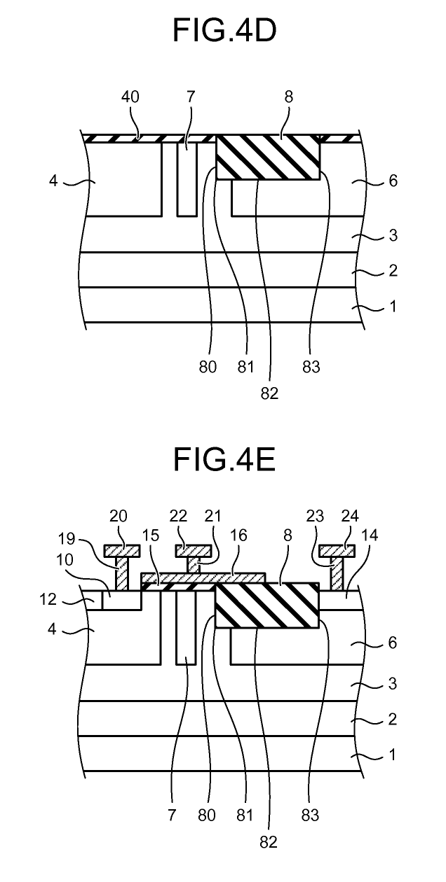

FIG. 5 is a view schematically showing the semiconductor device of the third embodiment of the present invention. The same reference numerals are used to denote constituents corresponding to those of the embodiments already described, and description thereof is omitted. The semiconductor device of the present embodiment has a P-type impurity region 7A having a higher P-type impurity concentration than the P-type epitaxial layer 3 and touching the N-type body regions (4, 5). Since having a higher impurity concentration than the P-type epitaxial layer 3, the P-type impurity region 7A is lower in resistance than the P-type epitaxial layer 3. Hence, a current path from the substrate surface via the P-type impurity region 7A to the P-type drift region 6 is more likely to be formed. That is, the current that flows from the P-type source regions (10, 11) to the P-type drift region 6 is spread toward the P-type semiconductor substrate 1, so that current flowing to the P-type drift region 6 but not via the corners (81, 91) of the buried insulating layers (8, 9) increases. Hence, the quantity of holes colliding with the source-side corners (81, 91) of the buried insulating layers (8, 9) located under the gate electrodes (16, 18) is reduced, so that the quantity of impact ions created at the source-side corners (81, 91) of the buried insulating layers (8, 9) is held down.

### Fourth Embodiment

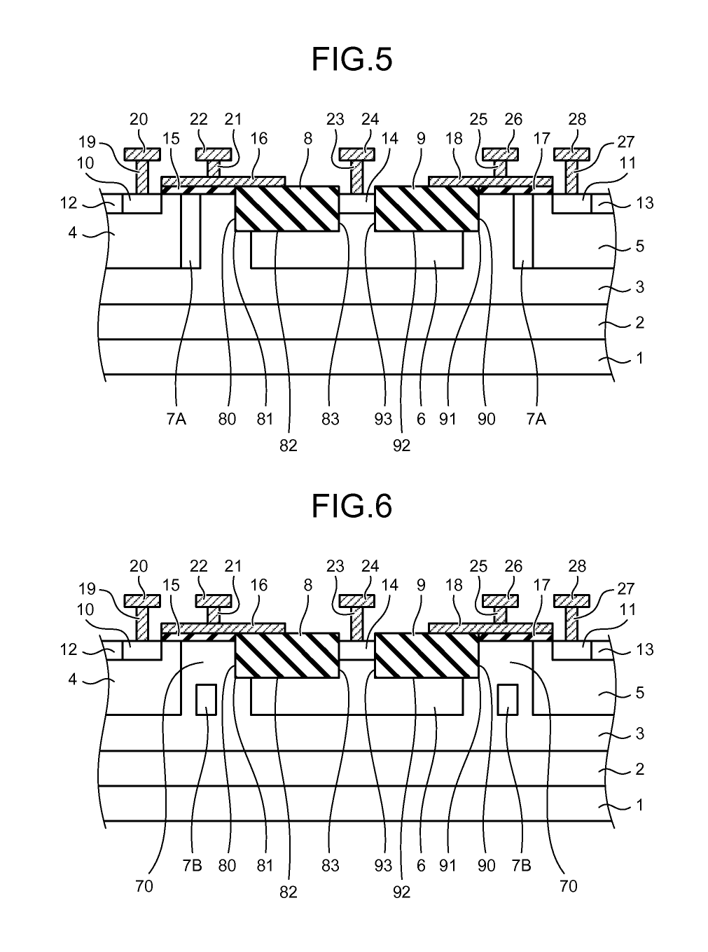

FIG. 6 is a view schematically showing the semiconductor device of the fourth embodiment of the present invention. The same reference numerals are used to denote constituents corresponding to those of the embodiments already described, and description thereof is omitted. In the semiconductor device of the present embodiment, a P-type impurity region 7B having a higher P-type impurity concentration than the P-type epitaxial layer 3 is provided at a position away from the substrate surface in part of the P-type epitaxial layer 3 between the N-type body region 4 and the buried insulating layer 8. That is, a P-type impurity region 70 of an impurity concentration nearly equal, e.g., to that of the P-type epitaxial layer 3 exists between the P-type impurity region 7B and the semiconductor substrate surface. With this configuration, the P-type impurity region 7B of low resistance exists only in lower portions of parts of the P-type epitaxial layer 3 between the N-type body regions (4, 5) and the P-type drift region 6.

Because the P-type impurity region 7B of low resistance exists, a current path via the P-type impurity region 7B to the P-type drift region 6 is more likely to be formed. That is, the current that flows from the P-type source regions (10, 11) to the P-type drift region 6 is spread toward the P-type semiconductor substrate 1, so that current flowing to the P-type drift region 6 via positions away from the source-side corners (81, 91) of the buried insulating layers (8, 9) increases. Hence, the quantity of holes colliding with the source-side corners (81, 91) of the buried insulating layers (8, 9) located under the gate electrodes (16, 18) is reduced, so that the quantity of impact ions created at the source-side corners (81, 91) of the buried insulating layers (8, 9) is held down. In the manufacturing method described with reference to FIG. 4, by introducing an N-type impurity selectively into the substrate surface at positions under which the P-type impurity region 7 is formed, the P-type impurity concentration of the P-type impurity region 70, which is on the substrate surface side of the P-type impurity region 7, can be reduced. Thus, the impurity concentration of the P-type impurity region 70 between the P-type impurity region 7B and the semiconductor substrate surface can be lowered to that of the P-type epitaxial layer 3. The P-type impurity region 7B is preferably, desirably provided below the bottoms of the buried insulating layers (8, 9). By providing the P-type impurity region 7B below the bottoms of the buried insulating layers (8, 9), the current path can be set to be away from the buried insulating layers (8, 9), and thus the creation of impact ions can be suppressed and current drive capability can be improved.

### Fifth Embodiment

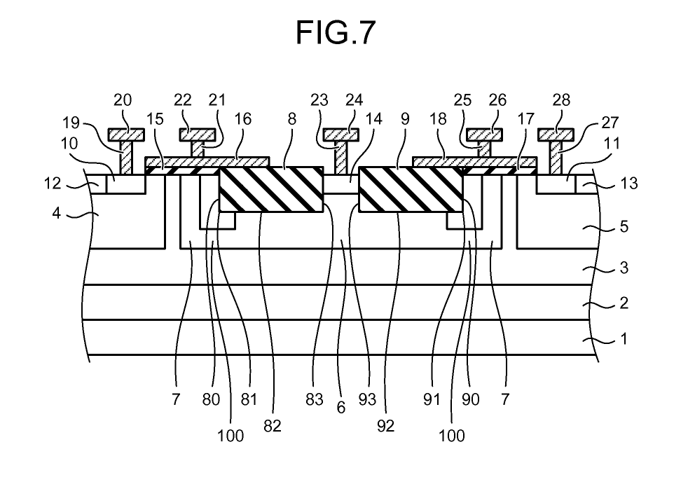

FIG. 7 is a view schematically showing the semiconductor device of the fifth embodiment of the present invention. The same reference numerals are used to denote constituents corresponding to those of the embodiments already described, and description thereof is omitted. The semiconductor device of the present embodiment has a P-type impurity connection region 100 connecting the P-type impurity region 7 and the P-type drift region 6. The P-type impurity connecting region 100 has a higher impurity concentration than the P-type epitaxial layer 3. Thus, the P-type drift region 6 and the P-type impurity region 7 are connected by the P-type impurity connection region 100 that has lower resistance than the P-type epitaxial layer 3. With this configuration, current is more likely to flow to the P-type drift region 6 via the P-type impurity region 7 and the P-type impurity connection region 100. Hence, the number of holes colliding with the source-side corners (81, 91) of the buried insulating layers (8, 9) is held down, so that the creation of impact ions is suppressed. The P-type impurity connection region 100 can be, for example, formed at a deep position in the P-type epitaxial layer 3 beforehand with high acceleration energy at ion implantation and be connected to the P-type impurity region 7 and the P-type drift region 6 by the process of forming the P-type impurity region 7 and the P-type drift region 6. It is preferable to connect the lower end portion of the P-type impurity region 7 with the lower portion of the P-type drift region 6 so as to avoid a situation that the P-type impurity connection region 100 covers the source-side corners (81, 91) of the buried insulating layers (8, 9).

Such a configuration that the impurity concentration of the P-type drift region 6 has a gradient can be made. If the impurity concentration is higher, the impurity more easily diffuses, e.g., in heat treatment after ion implantation. Hence, if the impurity concentration of the P-type drift region 6 near the source-side corners (81, 91) located on the source-side surfaces (80, 90) is high, the P-type impurity may diffuse due to heat treatment to cover the source-side corners (81, 91). If the source-side corners (81, 91) are covered by the P-type impurity having diffused from the P-type drift region 6, there occurs the risk that a structure exists where the vicinities of the source-side corners (81, 91) are lower in resistance and where thus current can more easily flow, so that impact ions are more likely to be created. Hence, for example, by lowering the impurity concentration of the N-type body region (4, 5) sides of the P-type drift region 6 to avoid that risk, a structure where the source-side corners (81, 91) are exposed to the P-type epitaxial layer 3 can be realized. Note that increasing the impurity concentration of the drain region 14 side of the P-type drift region 6 to make it lower in resistance can compensate for an increase in ON resistance caused by lowering the impurity concentration of the N-type body region (4, 5) sides of the P-type drift region 6. For example, by forming the P-type drift region 6 by multiple times of ion implantation with different amounts of impurity, the P-type drift region 6 can be made to have a concentration gradient.

Although embodiments of the P-type DMOS transistor have been described, the invention can also be applied to N-type DMOS transistors of the EDMOS structure. For example, after an N-type epitaxial layer is formed instead of the P-type epitaxial layer 3, with the conductivity types of impurity regions being likewise replaced with the opposite conductivity types, an N-type DMOS transistor can be formed.

A configuration can also be made where the gate wirings (22, 26) connected to the first gate electrode 16 and the second gate electrode 18 and the source wirings (20, 28) connected to the first source region 10 and the second source region 11 are connected in common so as to operate as one MOS transistor element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer of a first conductivity type;
a body region of a second conductivity type formed in the semiconductor layer;
a source region of the first conductivity type formed in the body region;
a drift region of the first conductivity type formed in the surface of the semiconductor layer and away from the body region;
a buried insulating layer formed in the surface of the semiconductor layer and away from the body region, wherein a first corner on the body region side of the buried insulating layer touches the semiconductor layer and a second corner on the far side from the body region touches the drift region;
a gate insulating layer formed on the surface of the semiconductor layer and between the source region and the buried insulating layer;
a gate electrode formed on the gate insulating layer;
an impurity region of the first conductivity type formed between the body region and the buried insulating layer and away from the buried insulating layer in the semiconductor layer, the impurity region having an impurity concentration higher than that of the semiconductor layer; and
a drain region of the first conductivity type formed in the drift region and touching the side surface on the far side of the buried insulating layer from the body region.

2. The semiconductor device according to claim 1, wherein the buried insulating layer is of an STI structure.

3. The semiconductor device according to claim 2, wherein the gate electrode extends onto the buried insulating layer.

4. The semiconductor device according to claim 2, wherein the impurity region touches the gate insulating layer.

5. The semiconductor device according to claim 4, wherein the first conductivity type is a P type, and the second conductivity type is an N type.

6. The semiconductor device according to claim 2, wherein the impurity region is located below the bottom of the buried insulating layer.

7. The semiconductor device according to claim 6, wherein the first conductivity type is a P type, and the second conductivity type is an N type.

8. The semiconductor device according to claim 2, wherein the impurity region touches the body region.

9. The semiconductor device according to claim 1, which has an impurity connection region of the first conductivity type that connects the impurity region and the drift region and that has a higher impurity concentration than the semiconductor layer.

10. The semiconductor device according to claim 1, wherein the impurity concentration of the source region side of the drift region is lower than that of the drain region side of the drift region.

11. A method for manufacturing a semiconductor device having a semiconductor layer of a first conductivity type comprising:
forming a buried insulating layer in the surface of the semiconductor layer;
forming a body region of a second conductivity type in the surface of the semiconductor layer and away from the buried insulating layer;
forming a drift region of the first conductivity type in the semiconductor layer;
forming an impurity region of the first conductivity type in the semiconductor layer and between the body region and the buried insulating layer,
forming a source region of the first conductivity type in the body region; and
forming a drain region of the first conductivity type on the far side of the buried insulating layer from the source region in the drift region;
wherein the forming of the drift region and the forming of the impurity region are performed simultaneously,
wherein the drift region exposing the side surface and corner on the source region side of the buried insulating layer to the semiconductor layer and touching the bottom of the buried insulating layer and the side surface on the far side of the buried insulating layer from the source region.

12. The method for manufacturing the semiconductor device according to claim 11, comprising forming a mask having a first opening located between the body region and the buried insulating layer and a second opening provided over the buried insulating layer,
wherein the drift region and the impurity region are formed by introducing an impurity of the first conductivity type into the semiconductor layer through the first and second openings of the mask.

13. A semiconductor device comprising:
a semiconductor layer of a first conductivity type;
a first body region of a second conductivity type formed in the semiconductor layer;
a second body region of the second conductivity type formed in the semiconductor layer;
a first source region of the first conductivity type formed in the first body region;
a second source region of the first conductivity type formed in the second body region;
a first buried insulating layer formed in the surface of the semiconductor layer and away from the first body region;
a second buried insulating layer formed in the surface of the semiconductor layer and away from the second body region;
a first gate insulating layer formed on the surface of the semiconductor layer and between the first source region and the first buried insulating layer;
a second gate insulating layer formed on the surface of the semiconductor layer and between the second source region and the second buried insulating layer;
a first gate electrode formed on the first gate insulating layer;
a second gate electrode formed on the second gate insulating layer;
a drift region of the first conductivity type formed in the semiconductor layer, the drift region exposing the side surface and corner located under the first gate electrode of the first buried insulating layer and the side surface and corner located under the second gate electrode of the second buried insulating layer to the semiconductor layer and touching the bottom of the first buried insulating layer, the bottom of the second buried insulating layer, the side surface on the far side of the first buried insulating layer from the first gate electrode and the side surface on the far side of the second buried insulating layer from the second gate electrode;
an impurity region of the first conductivity type surrounding, and away from, the first buried insulating layer and the second buried insulating layer in the semiconductor layer to be located between the first body region and the first buried insulating layer and between the second body region and the second buried insulating layer, the impurity region having an impurity concentration higher than that of the semiconductor layer; and
a drain region of the first conductivity type formed in the drift region and between the first buried insulating layer and the second buried insulating layer.

14. The semiconductor device according to claim 13, wherein the first buried insulating layer and the second buried insulating layer are of an STI structure.

15. The semiconductor device according to claim 14, wherein the first gate electrode extends onto the first buried insulating layer, and the second gate electrode extends onto the second buried insulating layer.

16. The semiconductor device according to claim 14, wherein the impurity region touches the first gate insulating layer and the second gate insulating layer.

17. The semiconductor device according to claim 14, wherein the impurity region is located below the bottoms of the first buried insulating layer and the second buried insulating layer.

18. The semiconductor device according to claim 14, wherein the impurity region touches the first body region and the second body region.

19. The semiconductor device according to claim 13, which has an impurity connection region of the first conductivity type that connects the impurity region and the drift region and that has a higher impurity concentration than the semiconductor layer.

20. The semiconductor device according to claim 13, wherein an impurity concentration of the first source region side and the second source region side of the drift region is lower than that of the drain region side of the drift region.
